(19) United States
(12) Patent Application Publication
(10) Pub. No.: US 2026/0171988 A1
(43) Pub. Date: Jun. 18, 2026

(54) DRIVER CIRCUIT

(71) Applicant: NIPPON TELEGRAPH AND TELEPHONE CORPORATION, Tokyo (JP)

(72) Inventor: Tadashi Minotani, Tokyo (JP)

(21) Appl. No.: 18/854,123

(22) PCT Filed: May 25, 2022
(86) PCT No.: PCT/JP2022/021352

§ 371 Date: Oct. 4, 2024

(51) Int. Cl. H03F 3/45; H03F 3/08; H03F 3/30; H03K 19/003; H03K 19/0185

(52) U.S. Cl. CPC H03F 3/45183; H03F 3/08; H03F 3/3013; H03F 3/45179; H03F 3/45475; H03K 19/00361; H03K 19/018521; H03F 2203/45512; H03F 2203/45722

(57) ABSTRACT

A driver circuit includes: a differential output circuit; a capacitor inserted between an output terminal on the positive phase side of the differential output circuit and an output terminal on the positive phase side of the driver circuit; a capacitor inserted between an output terminal on the negative phase side of the differential output circuit and an output terminal on the negative phase side of the driver circuit; and an offset circuit for applying offset voltages to output signals of the driver circuit in such a manner that the difference between a midpoint of the output signal on the positive phase side of the driver circuit and a midpoint of the output signal on the negative phase side of the driver circuit becomes equal to or greater than amplitudes of output signals of the differential output circuit.

### CROSS-REFERENCE TO RELATED APPLICATIONS

This application is a national phase entry of PCT Application No. PCT/JP2022/021352, filed on May 25, 2022, which application is hereby incorporated herein by reference.

### TECHNICAL FIELD

The present invention relates to a driver circuit for driving a load circuit such as an optical modulator.

### BACKGROUND

As the wired communication speed gets faster, a driver circuit, which is an output stage of a transmitter, is required to output a wide-band high-speed signal. In order to downsize the transmitter, a driver circuit composed of semiconductor transistors is used. However, a circuit using a semiconductor transistor cannot output an amplitude equal to or higher than the operating voltage of the circuit. In addition, although it is desirable to use a semiconductor transistor having a high current gain cutoff frequency ft for widening the band, the current gain cutoff frequency ft and the operating voltage have a trade-off relationship (see NPL 1). For this reason, if the driver circuit has a wide band, there is a problem that the amplitude of the output voltage is lowered.

### CITATION LIST

### Non Patent Literature

NPL 1 Akira Matsuzawa, “CMOS Device and RF Basic Building Block,” ISSCC Dig. Tech. Papers, p. 104, 2001, <https://www.apmc-mwe.org/mwe2005/src/TL/TL02-01.pdf>

### SUMMARY

### Technical Problem

Embodiments of the present invention are accomplished to solve the foregoing problem, and an object of embodiments of the present invention is to provide a wide-band driver circuit capable of obtaining an output voltage amplitude higher than a power supply voltage of a differential output circuit.

### Solution to Problem

A driver circuit of embodiments of the present invention includes: a differential input differential output type differential output circuit configured by transistors; a first capacitor inserted between an output terminal on a positive phase side of the differential output circuit and an output terminal on a positive phase side of the driver circuit; a second capacitor inserted between an output terminal on a negative phase side of the differential output circuit and an output terminal on a negative phase side of the driver circuit; and an offset circuit configured to apply an offset voltage to an output signal on the positive phase side and an output signal on the negative phase side of the driver circuit in such a manner that a difference between a midpoint of the output signal on the positive phase side of the driver circuit and a midpoint of the output signal on the negative phase side of the driver circuit becomes equal to or greater than an amplitude of the output signal of the differential output circuit.

In one configuration example of the driver circuit of the present invention, the offset circuit includes a first voltage generation unit configured to generate a first voltage, a second voltage generation unit configured to generate a second voltage lower than the first voltage, a first unity gain buffer configured to fix the midpoint of the output signal on the positive phase side of the driver circuit to the first voltage, and a second unity gain buffer configured to fix the midpoint of the output signal on the negative phase side of the driver circuit to the second voltage, wherein the difference between the first voltage and he second voltage is equal to or greater than the amplitude of the output signal of the differential output circuit.

Further, in one configuration example of the driver circuit of the present invention, the first unity gain buffer includes: a first operational amplifier having an inverting input terminal to which the first voltage is input; a pmos transistor having a gate terminal connected to an output terminal of the first operational amplifier, having a source terminal to which a power supply voltage is applied, and having a drain terminal connected to an output terminal on a positive phase side of the offset circuit; a first low-pass filter having an input terminal connected to the drain terminal of the pmos transistor and an output terminal connected to a non-inverting input terminal of the first operational amplifier; and a first resistor having one end connected to the drain terminal of the pmos transistor and the other end connected to the ground. The second unity gain buffer includes: a second operational amplifier having an inverting input terminal to which the second voltage is input; an nmos transistor having a gate terminal connected to an output terminal of the second operational amplifier, having a source terminal connected to the ground, and having a drain terminal connected to an output terminal on a negative phase side of the offset circuit; a second low-pass filter having an input terminal connected to the drain terminal of the nmos transistor and an output terminal connected to a non-inverting input terminal of the second operational amplifier; and a second resistor having one end connected to the drain terminal of the nmos transistor and having the power supply voltage applied to the other end.

Further, in one configuration example of the driver circuit of the present invention, the offset circuit includes: a first low-pass filter receiving input of an output signal on the positive phase side of the differential output circuit; a second low-pass filter receiving input of an output signal on the negative phase side of the differential output circuit; a replica circuit configured to output the same signal as an output signal of the differential output circuit when a signal is not input; a first difference circuit configured to output a difference between an output signal of the first low-pass filter and an output signal on a positive phase side of the replica circuit; a second difference circuit configured to output a difference between an output signal of the second low-pass filter and an output signal on a negative phase side of the replica circuit; a first bias addition circuit configured to superimpose an output signal of the first difference circuit on an output signal on a positive phase side of the driver circuit; and a second bias addition circuit configured to superimpose an output signal of the second difference circuit on an output signal on a negative phase side of the driver circuit.

In one configuration example of the driver circuit of the present invention, a time constant of a high-pass filter formed by the first capacitor and an output resistance of the first bias addition circuit is the same as a time constant of the first low-pass filter, and a time constant of a high-pass filter formed by the second capacitor and an output resistance of the second bias addition circuit is the same as a time constant of the second low-pass filter.

### Advantageous Effects

According to the present invention, an offset circuit is provided for applying offset voltages to the output signal on the positive phase side of the driver circuit and the output signal on the negative phase side of the driver circuit so that the difference between the midpoint of the output signal on the positive phase side of the driver circuit and the midpoint of the output signal on the negative phase side of the driver circuit is equal to or greater than the amplitude of the output signal of the differential output circuit. Thus, the wide-band driver circuit capable of obtaining an output voltage amplitude higher than a power supply voltage of the differential output circuit can be realized.

### BRIEF DESCRIPTION OF THE DRAWINGS

FIG. 1 is a block diagram showing a configuration of a driver circuit according to a first example of the present invention.

FIG. 2 is a diagram showing an example of the connection between the driver circuit according to the first example of the present invention and a load circuit.

FIG. 3 is a block diagram showing a configuration of a bias circuit according to the first example of the present invention.

FIG. 4 is a diagram showing a waveform of a differential signal input to a differential output circuit according to the first example of the present invention, a waveform of a differential signal output from the differential output circuit, and a waveform of a differential signal output from the driver circuit.

FIG. 5 is a block diagram showing a configuration of a driver circuit according to a second example of the present invention.

FIG. 6 is a block diagram showing a configuration of an offset circuit according to the second example of the present invention.

FIG. 7 is a waveform diagram for explaining operations of the offset circuit according to the second example of the present invention.

FIG. 8 is a waveform diagram for explaining operations of the offset circuit according to the second example of the present invention.

FIG. 9 is a diagram showing a waveform of a differential signal input to a differential output circuit according to the second example of the present invention, a waveform of a differential signal output from the differential output circuit, and a waveform of a differential signal output from the driver circuit.

### DETAILED DESCRIPTION OF ILLUSTRATIVE EMBODIMENTS

### First Example

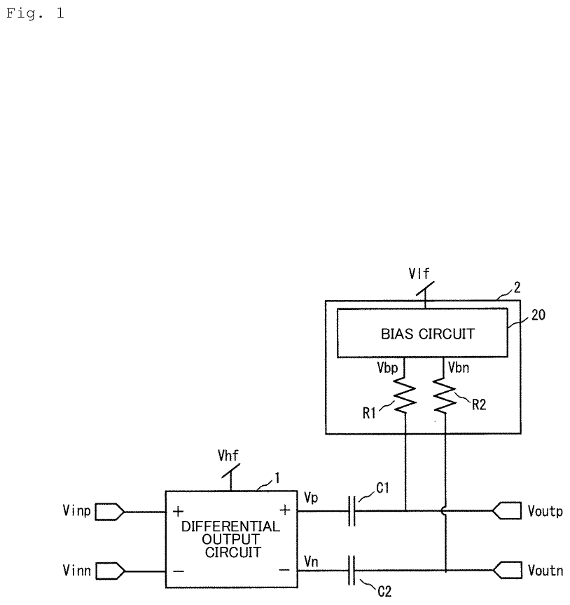

Examples of the present invention will be described hereinafter with reference to the drawings. FIG. 1 is a block diagram showing a configuration of a driver circuit according to a first example of the present invention. The driver circuit includes: a differential input differential output type differential output circuit 1 for amplifying differential signals Vinp, Vinn; a capacitor C1 inserted between an output terminal on the positive phase side of the differential output circuit 1 and an output terminal on the positive phase side of the driver circuit; a capacitor C2 inserted between an output terminal on the negative phase side of the differential output circuit 1 and an output terminal on the negative phase side of the driver circuit; and an offset circuit 2 for applying offset voltages to output signals Voutp and Voutn of the driver circuit so that the difference between a midpoint of the output signal Voutp on the positive phase side of the driver circuit and a midpoint of the output signal Voutn on the negative phase side of the driver circuit becomes equal to or greater than the amplitude of output signals Vp and Vn of the differential output circuit 1.

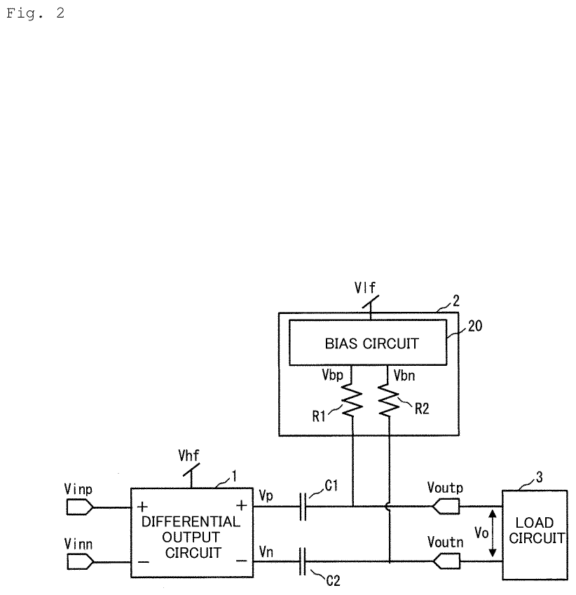

A load circuit 3 is connected to a differential output terminal of the driver circuit as shown in FIG. 2. The differential output circuit 1 serves to amplify the input differential signals Vinp and Vinn to a level at which the load circuit 3 can be driven. In the case of optical communication, a Mach-Zehnder (Mach-Zehnder) optical modulator or an electro-absorption (Electro-absorption) optical modulator is used as the load circuit 3.

As the configuration of the differential output circuit 1, any configuration of a differential input differential output type that operates by receiving supply of a power supply voltage Vhf can be applied. Examples of the differential output circuit 1 include a differential amplifier circuit. Alternatively, a configuration is possible in which a plurality of amplifier circuits may be connected in cascade manner. Alternatively, a variable gain amplifier circuit may be included in the configuration in which a plurality of amplifier circuits are connected in a cascade manner.

The offset circuit 2 is composed of a bias circuit 20 for outputting an offset voltage, a resistor R1 inserted between an output terminal on the positive phase side of the bias circuit 20 and an output terminal on the positive phase side of the driver circuit, and a resistor R2 inserted between an output terminal on the negative phase side of the bias circuit 20 and an output terminal on the negative phase side of the driver circuit. The resistors R1, R2 have the same value. However, the value of the resistors R1, R2 may be zero as described later.

An output terminal on the positive phase side of the offset circuit 2 is connected to the output terminal on the positive phase side of the differential output circuit 1 via the capacitor C1. An output terminal on the negative phase side of the offset circuit 2 is connected to the output terminal on the negative phase side of the differential output circuit 1 via the capacitor C2. The capacitors C1, C2 have the same value.

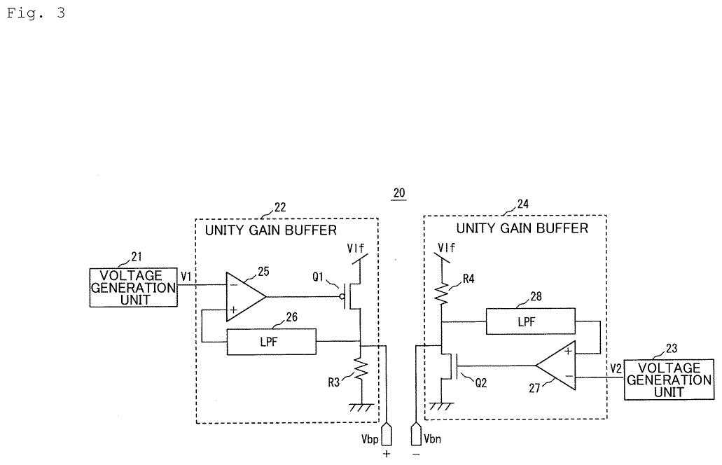

FIG. 3 shows a configuration example of the bias circuit 20. The bias circuit 20 includes a voltage generation unit 21 for generating a voltage V1 from a power supply voltage VIf (Vlf>Vhf), a unity gain buffer 22 for fixing a midpoint of an output signal Vbp on the positive phase side of the bias circuit 20 to the voltage V1, a voltage generation unit 23 for generating a voltage V2 (V2<V1) from the power supply voltage VIf, and a unity gain buffer 24 for fixing a midpoint of an output signal Vbn on the negative phase side of the bias circuit 20 to the voltage V2.

The unity gain buffer 22 includes: an operational amplifier 25 whose inverting input terminal receives the voltage V1; a pmos transistor Q1 whose gate terminal is connected to an output terminal of the operational amplifier 25, whose source terminal receives the power supply voltage Vlf, and whose drain terminal is connected to the output terminal on the positive phase side of the bias circuit 20; a low-pass filter (LPF) 26 whose input terminal is connected to the drain terminal of the transistor Q1 and whose output terminal is connected to a non-inverting input terminal of the operational amplifier 25; and a resistor R3 having one end is connected to the drain terminal of the transistor Q1 and the other end is connected to the ground.

The LPF 26 outputs an average voltage of the output signal Vbp on the positive phase side of the bias circuit 20. The operational amplifier 25 compares the output of the LPF 26 with the voltage V1. By controlling the transistor Q1 by the output of the operational amplifier 25, the output on the positive phase side of the bias circuit 20 is controlled so that the average of the output signal Vbp becomes V1.

The unity gain buffer 24 includes: an operational amplifier 27 whose inverting input terminal receives the voltage V2; an nmos transistor Q2 whose gate terminal is connected to an output terminal of the operational amplifier 27, whose source terminal is connected to the ground, and whose drain terminal is connected to the output terminal on the negative phase side of the bias circuit 20; an LPF 28 whose input terminal is connected to the drain terminal of the transistor Q2 and whose output terminal is connected to a non-inverting input terminal of the operational amplifier 27; and a resistor R4 having one end connected to the drain terminal of the transistor Q2 and having the other end to which the power supply voltage VIf is supplied.

The LPF 28 outputs an average voltage of the output signal Vbn on the negative phase side of the bias circuit 20. The operational amplifier 27 compares the output of the LPF 28 with the voltage V2. By controlling the transistor Q2 by the output of the operational amplifier 27, the output on the negative phase side of the bias circuit 20 is controlled in such a manner that the average of the output signal Vbn becomes V2. The resistors R3, R4 have the same value. The time constant of the LPF 26 and the time constant of the LPF 28 are the same.

In the present example, the average of the output signals on the positive phase side of the bias circuit 20 is fixed to V1, and the average of the output signals Vbn on the negative phase side is fixed to V2. Therefore, when the load circuit 3 is an electroabsorption optical modulator, the fluctuation of the offset V1-V2 on the positive phase side and the negative phase side due to a photoelectric current generated from the optical modulator can be suppressed.

When the configuration of the present example is used, the values of the resistors R1, R2 may be zero. In this case, the output terminal on the positive phase side of the bias circuit 20 is connected to the output terminal on the positive phase side of the driver circuit, and the output terminal on the negative phase side of the bias circuit 20 is connected to the output terminal on the negative phase side of the driver circuit.

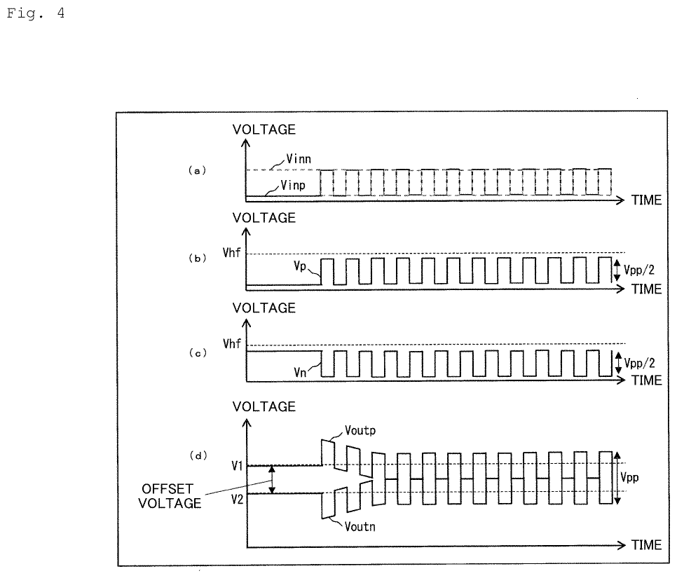

FIG. 4 shows waveforms of the differential signals Vinp, Vinn input to the differential output circuit 1, waveforms of the differential signals Vp, Vn output from the differential output circuit 1, and waveforms of the differential signals Voutp, Voutn output from the driver circuit. As shown in FIG. 4(a), the differential signals Vinp, Vinn are input to the differential output circuit 1, and as shown in FIG. 4(b) and 4(c), the differential signals Vp, Vn having an amplitude Vpp/2 lower than power supply voltage Vhf are output from the differential output circuit 1.

In a state where a high frequency signal is not input to the differential output circuit 1, as shown in FIG. 4(d), the voltage of the output Voutp on the positive phase side of the driver circuit is biased to V1, and the voltage of the output Voutn on the negative phase side is biased to V2. When a high frequency signal is input to the differential output circuit 1, the output signal Voutp on the positive phase side of the driver circuit changes around V1 after going through a transient state, and the output signal Voutn on the negative phase side changes around V2. That is, the midpoint of the output signal Voutp on the positive phase side of the driver circuit becomes V1, and the midpoint of the output signal Voutn on the negative phase side becomes V2.

The voltage of the difference between the output signal Voutp on the positive phase side of the driver circuit and the output signal Voutn on the negative phase side is applied to the load circuit 3. When the difference between the voltages V1 and V2 is Vpp/2, a voltage of Vpp at the maximum is applied. That is, a high frequency signal having an amplitude Vpp is applied to the load circuit 3. Since the power supply voltage of the differential output circuit 1 can be set to Vhf lower than Vpp, the differential output circuit 1 can be constituted of a transistor having a high current gain cutoff frequency ft.

As described above, the present example can realize a wide-band driver circuit capable of obtaining an output voltage amplitude higher than the power supply voltage Vhf of the differential output circuit 1.

Although the difference between the voltages V1 and V2 is set to Vpp/2 in the above description, the difference between the voltages V1 and V2 may be set to be greater than Vpp/2 when the application of a bias voltage equal to or higher than zero to the load circuit 3 is desired.

### Second Example

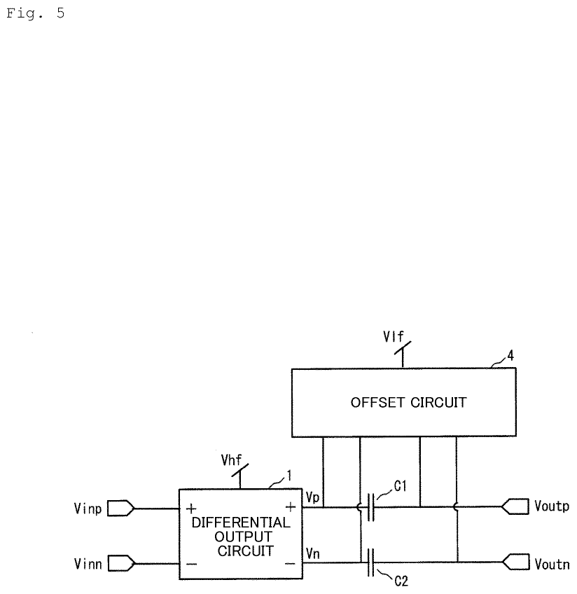

A second example of the present invention will be described next. FIG. 5 is a block diagram showing a configuration of a driver circuit according to the second example of the present invention. The driver circuit of the present example includes: a differential output circuit 1; capacitors C1 and C2; and an offset circuit 4 for applying an offset voltage to an output signal of the driver circuit and suppressing a change in an output signal of the driver circuit caused by a transient change in a DC component of an AC signal output from the differential output circuit 1. As in the first example, a load circuit is connected to a differential output terminal of the driver circuit.

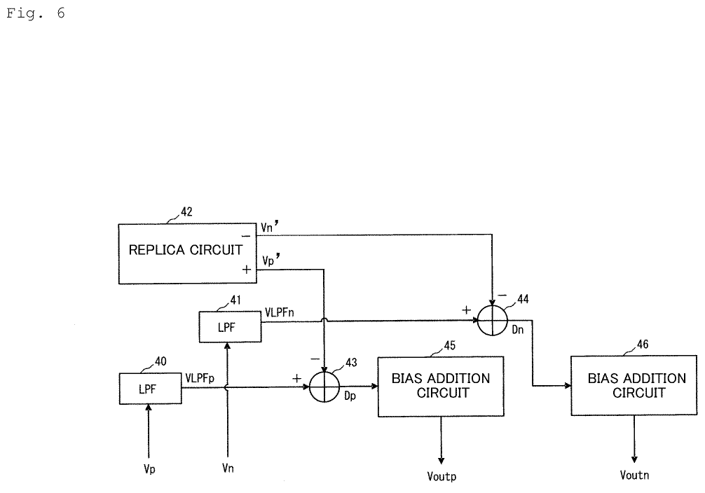

FIG. 6 shows a configuration example of the offset circuit 4. The offset circuit 4 includes: an LPF 40 for inputting the output signal Vp on the positive phase side of the differential output circuit 1; an LPF 41 for inputting the output signal Vn on the negative phase side of the differential output circuit 1; a replica circuit 42 for outputting the same signal as the output signals Vp, Vn of the differential output circuit 1 when no high frequency signal is input; a difference circuit 43 for outputting the difference between an output signal VLPFp of the LPF 40 and an output signal Vp′ on the positive phase side of the replica circuit 42; a difference circuit 44 for outputting the difference between an output signal VLPFn of the LPF 41 and an output signal Vn′ on the negative phase side of the replica circuit 42; a bias addition circuit 45 for superimposing an output signal of the difference circuit 43 on the output signal Voutn on the positive phase side of the driver circuit; and a bias addition circuit 46 for superimposing an output signal of the difference circuit 44 on the output signal Voutn on the negative phase side of the driver circuit.

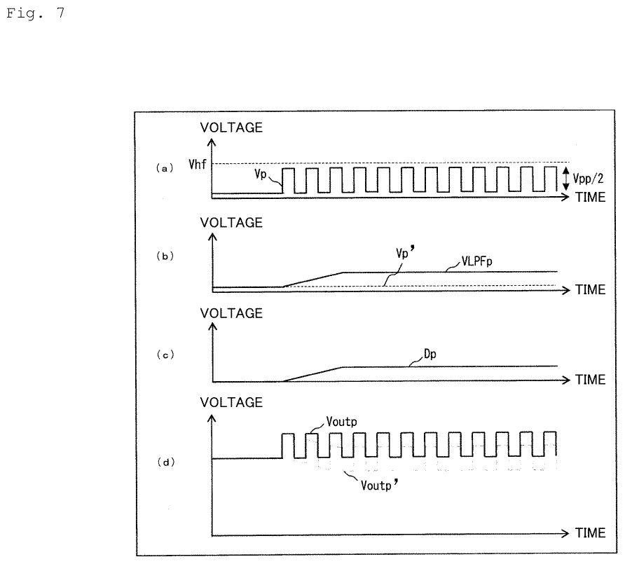

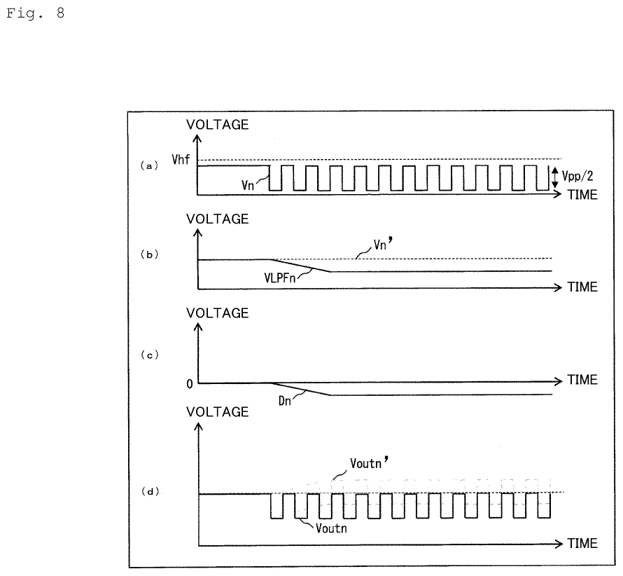

Operations of the offset circuit 4 will be described with reference to FIGS. 7 and 8. The replica circuit 42 outputs the same voltages Vp′, Vn′ as the output signals Vp, Vn of the differential output circuit 1 when no signal is present (FIGS. 7 and 8(b)). When a high frequency signal is input to the differential output circuit 1, the output VLPFp of the LPF 40 changes toward the midpoint of the output signal Vp on the positive phase side of the differential output circuit 1 due to the characteristics of a transient response determined by the time constant of the LPF 40, as shown in FIG. 7(b). Similarly, the output VLPFn of the LPF 41 changes toward the midpoint of the output signal Vn on the negative phase side of the differential output circuit 1 due to the characteristics of a transient response determined by the time constant of the LPF 41, as shown in FIG. 8(b).

A high-pass filter is formed by the capacitor C1 and the output resistance of the bias addition circuit 45, and similarly, a high-pass filter is formed by the capacitor C2 and the output resistance of the bias addition circuit 46. Therefore, when there is no processing in the offset circuit 4, the midpoints of the output signals Voutp, Voutn of the driver circuit are asymptotically close to the bias voltage (Vp′, Vn′) when there is no signal due to the characteristics of a transient response determined by the time constant of the high-pass filter.

The difference circuit 43 outputs a difference Dp between the output signal VLPFp of the LPF 40 and the output signal Vp′ on the positive phase side of the replica circuit 42. As shown in FIG. 7(c), the signal Dp represents the fluctuation component of the midpoint of the output signal Vp on the positive phase side of the differential output circuit 1. Similarly, the difference circuit 44 outputs a difference Dn between the output signal VLPFn of the LPF 41 and the output signal Vn′ on the negative phase side of the replica circuit 42. As shown in FIG. 8(c), the signal Dn represents the fluctuation component of the midpoint of the output signal Vn on the negative phase side of the differential output circuit 1.

The bias addition circuit 45 superimposes an output voltage Dp of the difference circuit 43 on the output signal Voutp on the positive phase side of the driver circuit. The bias addition circuit 46 superimposes an output voltage Dn of the difference circuit 44 on the output signal Voutn on the negative phase side of the driver circuit. Thus, as shown in FIG. 7(d) and FIG. 8(d), variation in the midpoints of the output signals Voutp, Voutn of the driver circuit when high frequency signals Vinp, Vinn are input can be suppressed. Voutp′ shown in FIG. 7(d) and Voutn′ shown in in FIG. 8(d) represent the output signals Voutp and Voutn, respectively, when the voltage fluctuation is not suppressed by the offset circuit 4.

The time constant of the high-pass filter formed by the capacitor C1 and the output resistance of the bias addition circuit 45 is made equal to the time constant of the LPF 40, and the time constant of the high-pass filter formed by the capacitor C2 and the output resistance of the bias addition circuit 46 is made equal to the time constant of the LPF 41. Thus, even within a time until the outputs VLPFp, VLPFn of the LPFs 40, 41 are stabilized at the midpoints of the output signals Vp, Vn of the differential output circuit 1, fluctuations of the midpoints of the output signals Voutp, Voutn of the driver circuit can be suppressed.

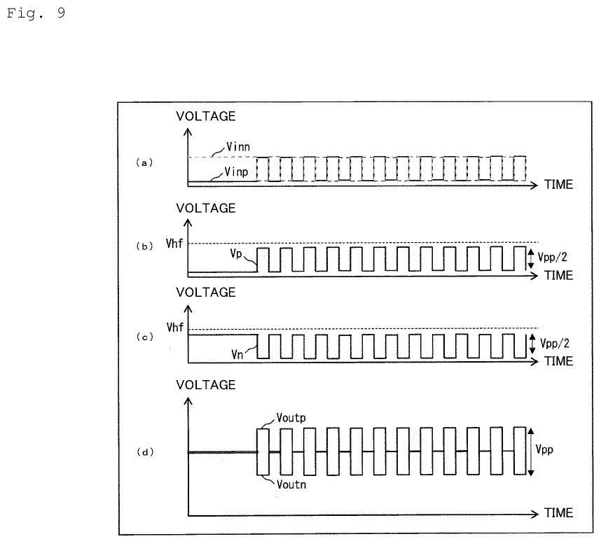

FIG. 9 shows waveforms of the differential signals Vinp, Vinn input to the differential output circuit 1, waveforms of the differential signals Vp, Vn output from the differential output circuit 1, and waveforms of the differential signals Voutp, Voutn output from the driver circuit. As shown in FIG. 9(a), the differential signals Vinp, Vinn are input to the differential output circuit 1, and as shown in FIG. 9(b) and 9(c), the differential signals Vp, Vn having an amplitude Vpp/2 lower than power supply voltage Vhf are output from the differential output circuit 1.

A high frequency signal is applied to the load circuit through the capacitors C1, C2, wherein a high frequency signal of a constant amplitude is applied without a transient fluctuation in the high frequency signal, by the operations of the offset circuit 4. The voltage of the difference between the output signal Voutp on the positive phase side of the driver circuit and the output signal Voutn on the negative phase side is applied to the load circuit. Therefore, a high frequency signal having an amplitude Vpp is applied to the load circuit. The difference between the midpoint of the output signal Voutp on the positive phase side and the midpoint of the output signal Voutn on the negative phase side is Vpp/2.

As with the first example, since the power supply voltage of the differential output circuit 1 can be set to Vhf lower than Vpp, the differential output circuit 1 can be constituted of transistors having the high current gain cutoff frequency ft. Thus, the present example can realize a wide-band driver circuit capable of obtaining an output voltage amplitude higher than the power supply voltage Vhf of the differential output circuit 1.

### INDUSTRIAL APPLICABILITY

Embodiments of the present invention can be applied to a driver circuit.

### REFERENCE SIGNS LIST

1 Differential output circuit
2,4 Offset circuit
3 Load circuits
20 Bias circuits
21, 23 Voltage generation unit
22, 24 Unity gain buffer
25, 27 Operational amplifier
26, 28, 40, 41 Low pass filters
42 Replica circuits
43, 44 Difference circuit
45, 46 Bias addition circuit
Q1 pmos transistor
Q2 nmos transistor
C1, C2 Capacitor
R1 to R4 Resistor

1-5. (canceled)

6. A driver circuit, comprising:
a differential output circuit comprising transistors, wherein the differential output circuit is of a differential input differential output type;
a first capacitor between an output terminal on a positive phase side of the differential output circuit and an output terminal on a positive phase side of the driver circuit;
a second capacitor between an output terminal on a negative phase side of the differential output circuit and an output terminal on a negative phase side of the driver circuit; and
an offset circuit configured to apply offset voltages to an output signal on the positive phase side of the driver circuit and an output signal on the negative phase side of the driver circuit in such a manner that a difference between a midpoint of the output signal on the positive phase side of the driver circuit and a midpoint of the output signal on the negative phase side of the driver circuit is equal to or greater than an amplitude of an output signal of the differential output circuit.

7. The driver circuit according to claim 6, wherein the offset circuit includes:
a first voltage generation circuit configured to generate a first voltage;
a second voltage generation circuit configured to generate a second voltage lower than the first voltage;
a first unity gain buffer configured to fix a midpoint of the output signal on the positive phase side of the driver circuit to the first voltage; and
a second unity gain buffer configured to fix a midpoint of the output signal on the negative phase side of the driver circuit to the second voltage, a difference between the first voltage and the second voltage being equal to or greater than the amplitude of the output signal of the differential output circuit.

8. The driver circuit according to claim 7, wherein:
the first unity gain buffer includes:
a first operational amplifier having an inverting input terminal to which the first voltage is input;
a first transistor having a gate terminal connected to an output terminal of the first operational amplifier, a source terminal to which a power supply voltage is applied, and a drain terminal connected to an output terminal on a positive phase side of the offset circuit;
a first low-pass filter having an input terminal connected to a drain terminal of the first transistor and an output terminal connected to a non-inverting input terminal of the first operational amplifier; and
a first resistor having a first end connected to the drain terminal of the first transistor and a second end connected to the ground, and wherein
the second unity gain buffer includes:
a second operational amplifier having an inverting input terminal to which the second voltage is input;
a second transistor having a gate terminal connected to an output terminal of the second operational amplifier, a source terminal connected to the ground, and a drain terminal connected to an output terminal on a negative phase side of the offset circuit;
a second low-pass filter having an input terminal connected to the drain terminal of the second transistor and an output terminal connected to a non-inverting input terminal of the second operational amplifier; and
a second resistor having a first end connected to the drain terminal of the second transistor and a second to which the power supply voltage is applied.

9. The driver circuit according to claim 8, wherein the first transistor is of an opposite type as the second transistor.

10. The driver circuit according to claim 9, wherein the first transistor is a PMOS transistor, and wherein the second transistor is an NMOS transistor.

11. The driver circuit according to claim 6, wherein the offset circuit includes:
a first low-pass filter for receiving an input of the output signal on the positive phase side of the differential output circuit;
a second low-pass filter for receiving an input of the output signal on the negative phase side of the differential output circuit;
a replica circuit configured to output a same signal as an output signal of the differential output circuit when no signal is input;
a first difference circuit configured to output a difference between an output signal of the first low-pass filter and an output signal on the positive phase side of the replica circuit;
a second difference circuit configured to output a difference between an output signal of the second low-pass filter and an output signal on the negative phase side of the replica circuit;
a first bias addition circuit configured to superimpose an output signal of the first difference circuit on the output signal on the negative phase side of the driver circuit; and
a second bias addition circuit configured to superimpose an output signal of the second difference circuit on the output signal on the negative phase side of the driver circuit.

12. The driver circuit according to claim 11, wherein
a time constant of a high-pass filter provided by the first capacitor and an output resistance of the first bias addition circuit is the same as a time constant of the first low-pass filter; and
a time constant of a high-pass filter provided by the second capacitor and an output resistance of the second bias addition circuit is the same as a time constant of the second low-pass filter.

13. A driver circuit, comprising:
a differential output circuit; and
an offset circuit configured to apply offset voltages to an output signal on a positive phase side of the driver circuit and an output signal on a negative phase side of the driver circuit such that a difference between a midpoint of the output signal on a positive phase side of the driver circuit and a midpoint of the output signal on a negative phase side of the driver circuit is equal to or greater than an amplitude of an output signal of the differential output circuit.

14. The driver circuit according to claim 13, further comprising:
a first capacitor between an output terminal on the positive phase side of the differential output circuit and an output terminal on the positive phase side of the driver circuit.

15. The driver circuit according to claim 13, further comprising:
a second capacitor between an output terminal on the negative phase side of the differential output circuit and an output terminal on the negative phase side of the driver circuit.

16. The driver circuit according to claim 13, wherein the offset circuit includes:
a first voltage generation circuit configured to generate a first voltage;
a second voltage generation circuit configured to generate a second voltage lower than the first voltage;
a first unity gain buffer configured to fix a midpoint of the output signal on the positive phase side of the driver circuit to the first voltage; and
a second unity gain buffer configured to fix a midpoint of the output signal on the negative phase side of the driver circuit to the second voltage, a difference between the first voltage and the second voltage being equal to or greater than the amplitude of the output signal of the differential output circuit.

17. The driver circuit according to claim 16, wherein:
the first unity gain buffer includes:
a first operational amplifier having an inverting input terminal to which the first voltage is input;
a first transistor having a gate terminal connected to an output terminal of the first operational amplifier, a source terminal to which a power supply voltage is applied, and a drain terminal connected to an output terminal on a positive phase side of the offset circuit;
a first low-pass filter having an input terminal connected to a drain terminal of the first transistor and an output terminal connected to a non-inverting input terminal of the first operational amplifier; and
a first resistor having a first end connected to the drain terminal of the first transistor and a second end connected to the ground;
the second unity gain buffer includes:
a second operational amplifier having an inverting input terminal to which the second voltage is input;
a second transistor having a gate terminal connected to an output terminal of the second operational amplifier, a source terminal connected to the ground, and a drain terminal connected to an output terminal on a negative phase side of the offset circuit;
a second low-pass filter having an input terminal connected to the drain terminal of the second transistor and an output terminal connected to a non-inverting input terminal of the second operational amplifier; and
a second resistor having a first end connected to the drain terminal of the second transistor and a second to which the power supply voltage is applied; and
the first transistor is a PMOS transistor, and wherein the second transistor is an NMOS transistor.

18. The driver circuit according to claim 13, wherein the offset circuit includes:
a first low-pass filter for receiving an input of the output signal on the positive phase side of the differential output circuit;
a second low-pass filter for receiving an input of the output signal on the negative phase side of the differential output circuit;
a replica circuit configured to output a same signal as an output signal of the differential output circuit when no signal is input;
a first difference circuit configured to output a difference between an output signal of the first low-pass filter and an output signal on the positive phase side of the replica circuit;
a second difference circuit configured to output a difference between an output signal of the second low-pass filter and an output signal on the negative phase side of the replica circuit;
a first bias addition circuit configured to superimpose an output signal of the first difference circuit on the output signal on the negative phase side of the driver circuit; and
a second bias addition circuit configured to superimpose an output signal of the second difference circuit on the output signal on the negative phase side of the driver circuit.

19. The driver circuit according to claim 18, wherein
a time constant of a high-pass filter provided by a first capacitor and an output resistance of the first bias addition circuit is the same as a time constant of the first low-pass filter, the first capacitor being coupled to an output terminal on the positive phase side of the differential output circuit; and
a time constant of a high-pass filter provided by a second capacitor and an output resistance of the second bias addition circuit is the same as a time constant of the second low-pass filter, the second capacitor being coupled to an output terminal on the negative phase side of the differential output circuit.
